(19) United States
(12) Patent Application Publication
(10) Pub. No.: US 2004/0239315 A1
(43) Pub. Date: Dec. 2, 2004

(54) Testing apparatus and a testing method

(75) Inventors: Takahisa Mihara, Hyogo (JP); Eiji Ishimto, Hyogo (JP)

Correspondence Address: Paul D. Greeley, Esq., Ohlandt, Greeley, Ruggiero & Perle, L.L.P., 10th Floor, One Landmark Square, Stamford, CT, 06901-2682, US

(73) Assignee: AGILENT TECHNOLOGIES, INC.

(21) Appl. No.: 10/858,962

(22) Filed: Jun. 2, 2004

(30) Foreign Application Priority Data
Jun. 2, 2003 (JP) 2003-156979

(51) Int. Cl. G01R 33/12

(52) U.S. Cl. 324/210; 324/212

(57) ABSTRACT

A testing apparatus for testing a disk and/or head of a disk drive that includes a disk rotating device that rotates the disk and a rotary-positioning device that rotates and positions the head, with the rotary-positioning device supporting the head such that the attitude of the head relative to the center of rotation of the rotary-positioning device is tilted in comparison to the attitude of the head relative to the rotation center of the head in the disk drive.

### BACKGROUND OF THE INVENTION

1. Field of the Invention

The present invention relates to an apparatus and a method for testing a head and/or a disk.

2. Discussion of the Background Art

Conventional disk and head testing apparatuses test placing heads and disks same as the placement in a disk drive in which the heads and the disks are installed (see Japanese Kokai 2000-187,821 (pages 4 and 5, FIGS. 1 and 2), Japanese Kokai 6[1994]-350,269 (pages 4 and 5, FIG. 3), and Japanese Kokai 5[1993]-298,632 (page 2).

For instance, conventional head or disk testing apparatuses comprise a disk rotating device that supports and rotates a disk, an arm that supports a head, a rotation-positioning device that rotates and positions the arm, and a relative positioning means that positions the disk rotating device and rotation-positioning device relative to one another. Arm length is equal to the length of the arm inside the disk drive in which the head and disk are installed. Moreover, the relative distance between the disk rotating device and the arm is equal to the relative distance between the disk rotating device and the arm inside the disk drive in which the head and disk have been installed. This is because the head or disk testing specifications are prescribed such that a pre-determined skew angle is produced at a pre-determined radial position of the head on the disk when the head or disk is being tested (e.g., Japanese Kokai 2000-187,821, pages 4 and 5, FIGS. 1 and 2). Skew angle is discussed in detail below.

This type of required radial position and skew diameter exists for all heads and disks. Thus, conventional head or disk testing apparatuses are adapted to being capable of producing various radial positions and skew angles.

There is a type of head called una-mounthereinafter referred to as a una-mount head. Conventional heads have a slider with a write element and a read element, a suspension that supports the slider, and a mounting plate that supports the suspension. The una-mount head has a structure characterized in that it the mounting plate is extended and the center of rotation of the head is embedded in the mounting plate. Due to the structure of the una-mount head, the structure of the disk drive can be simplified and reduced in size, as compared to other types of heads.

The outer shape of una-mount head 100 is shown in FIGS. 1 and 2. FIGS. 1 and 2 show the front surface and back surface, respectively, of una-mount head 100. Slider 110, suspension 120, and mounting plate 130 are as described above. Moreover, bearing 140 is the part that attaches una-mount head 100 to the rotation-positioning device. Center C₁ is the center of bearing 140, and una-mount head 100 rotates around center C₁. Gap center line G is the gap center line of slider 110.

FIG. 3 is an enlarged, detailed view of slider 110 shown in FIG. 2. In FIG. 3 the slider surface that faces the disk is illustrated. Slider 110 has gap 111 of the write element and gap 112 of the read element. The gap of the write element is generally referred to as the write gapand the gap of the read element is generally referred to as the read gap. Furthermore, the center of the gap for the write element and the center of the gap for the read element are simply referred to as the gap center or the gap position.

Head inspection specifications determine whether the gap center is for the write element or for the read element. Gap center 113 in FIG. 3 is the center of gap 111 of the write element. Unless otherwise specified, the gap center in the present specification refers to the gap center of the write element.

Gap center line G in FIG. 3 is a straight line passing through the center of gap 111 of the write element that is orthogonal to gap 111 of the write element. Unless otherwise noted, the gap center line in the present specification refers to a straight line passing through the gap center of the write element that is orthogonal to the gap of the write element

In accordance with the foregoing described terms, stating the head is positioned on the track means that the gap center of that head is positioned on the track. Moreover, the skew angle is the tilt in the circumferential direction of the head positioned on the disk. More specifically, the skew angle is the angle that is formed by the gap center line of the head positioned on a track on a disk and the tangent of the track circle at the gap center of that head. The skew angle is positive when the gap center line that extends from the gap of the head in the direction of the mounting plate opens to the periphery side of disk relative to the tangent of the track circle at the gap center of the head. Moreover, the skew angle is zero when this gap center line overlaps the tangent and is negative when it opens to inner side of disk.

FIGS. 4 and 5 show how una-mount head 100 is positioned. Part of disk 200 has been eliminated from FIG. 5 in order to simplify the drawing. Una-mount head 100a and una-mount head 100b have the same function and structure as una-mount head 100. Una-mount head 100a and una-mount head 100b are placed such that the sliders are opposite one another and they hold disk 200. Una-mount head 100a and una-mount head 100b are located very close to the outer periphery of disk 200 and part thereof overlaps disk 200. Part of disk 200 in FIG. 5 is cut away so that the movement of una-mount head 100b can be seen.

When a conventional head or disk testing apparatus is used, the head is placed as it is when it is housed inside an actual disk drive. Consequently, the una-mount head as a whole comes very close to the outer periphery and part thereof overlaps the disk. When the head is being attached and detached, it must be moved far enough away from the disk to prevent the head and disk from touching and to prevent accidents of disk break-away.

Therefore, a drive mechanism for pulling the entire rotation-positioning device from the disk rotating device is needed with conventional head or disk testing apparatuses.

Simplified and smaller testing apparatuses are needed for mass inspection of heads and disks. However, a drive mechanism for pulling the entire rotation-positioning device away from the disk rotation device is a factor that impedes simplification and a reduction in size of the testing apparatus.

Therefore, in light of the foregoing problems, the present invention provides a small, simple testing apparatus and method for sufficiently pulling the head and disk away from one another when the head is being attached and detached while satisfying the necessary testing specifications and without restricting the type of head that is used. Moreover, the present invention also provides a testing method that is necessary for this type of testing apparatus.

### SUMMARY OF THE INVENTION

The present invention is a testing apparatus that tests a disk and/or head of a disk drive comprising a disk rotation device that rotates the disk and a rotary-positioning device that rotates and positions the head, with this rotary-positioning device being such that the head is supported so that the attitude of the head relative to the center of rotation of the rotary-positioning device is tilted in comparison to the attitude of the head relative to the center of rotation of the head inside the disk drive.

Moreover, in order to solve the above-mentioned problems, the present invention provides a method of inspection using a disk rotation device and a rotary-positioning device comprising a step whereby the head is positioned by the rotary-positioning device such that the attitude of the head relative to the center of rotation of the rotary-positioning device is tilted in comparison to the attitude of the head relative to the center of rotation of the head inside the disk drive.

The rotary-positioning device supports the head such that the angle that is formed by the gap center line of the head and the line that passes through the center of rotation of the rotary-positioning device and the gap center of the head is set to an offset value in comparison to the angle that is formed by the gap center line of the head and the line that passes through the center of rotation of the head and the gap center of the head in the disk drive.

The testing apparatus is adapted so that the following formula is satisfied when the head is positioned on the first track on the disk; and the distance between the center of rotation of the disk rotation device and the center of rotation of the rotary-positioning device is D, the distance between the center of rotation of this rotary-positioning device, and the gap center of the head is L, the radius of the first track is R_{X}, the necessary skew angle of the head on the first track is α_{X}, and the offset angle is φ.

$$D = \sqrt{{L}^{2} - 2 L {R}_{X} cos ( {α}_{X} + φ + \frac{π}{2} ) + {R}_{X}^{2}}$$

The testing apparatus is also adapted so that the following formulas are satisfied when the head is positioned on the first track and the second track on the disk and the distance between the center of rotation of the disk rotation device and the center of rotation of the rotation-positioning device is D, the distance between the center of rotation of the rotation-positioning device and the gap center of the head is L, the radius of the first track is R_{X}, the radius of the second track is R_{Y}, the necessary skew angle of the head on the first track is α_{X}, the necessary skew angle of the head on the second track is α_{Y}, and the offset angle is φ.

$$D = \sqrt{{L}^{2} - 2 L {R}_{X} cos ( {α}_{X} + φ + \frac{π}{2} ) + {R}_{X}^{2}}$$

$$L = \frac{{R}_{Y}^{2} - {R}_{X}^{2}}{2 \{ {R}_{Y} cos ( {α}_{Y} + φ + \frac{π}{2} ) - {R}_{X} cos ( {α}_{X} + φ + \frac{π}{2} ) \}}$$

The testing apparatus preferably includes a head that is a una-mount head.

The present invention provides a method for testing a disk and/or head of a disk drive using a disk rotation device and a rotary-positioning device, the method comprising rotating the disk by the disk rotation device; and supporting and positioning the head by the rotary-positioning device such that the attitude of the head relative to the center of rotation of the rotation-positioning device is tilted in comparison with the attitude of the head relative to the center of rotation of the head in the disk drive.

According to the present invention, away from the disk rotation device, the head and disk can be pulled far enough away from one another when the head is being attached and detached while satisfying the necessary testing specifications without restricting the type of head that is used, and without a drive mechanism for pulling the entire rotation-positioning device.

These and other aspects, embodiments, and features of the present invention will be further disclosed in the following drawings and detailed description.

### BRIEF DESCRIPTION OF THE DRAWINGS

FIG. 1 is a drawing showing a una-mount head according to the prior art;

FIG. 2 is a drawing showing a una-mount head according to the prior art;

FIG. 3 is a drawing showing the slider of a una-mount head according to the prior art;

FIG. 4 is a drawing showing the positioning operation of the una-mount head according to the prior art;

FIG. 5 is a drawing showing the positioning operation of the una-mount head according to the prior art;

FIG. 6 is a drawing showing testing apparatus 300, which is an example of the present invention;

FIG. 7 is a top view showing part of testing apparatus 300 according to the present invention;

FIG. 8 is another top view showing part of testing apparatus 300 according to the present invention; and

FIG. 9 depicts a testing apparatus 400 according to the present invention.

### DETAILED DESCRIPTION OF THE PREFERRED EMBODIMENT

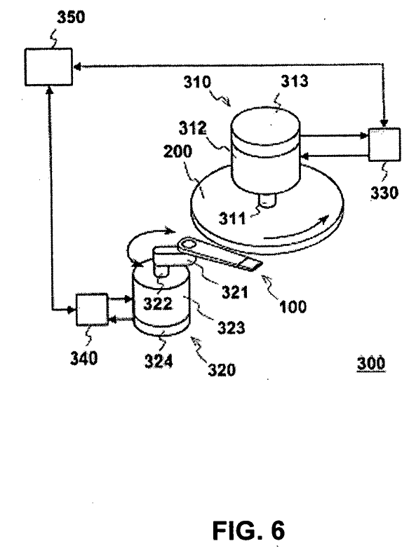

The present invention is described hereafter based on the preferred embodiments shown in the attached drawings. The embodiment of the present invention is an apparatus for inspecting a head or a disk, a schematic drawing thereof is shown in FIG. 6.

First, 300 in FIG. 6 comprises a disk rotating device 310 that supports and rotates the disk, a rotary-positioning device 320 that positions una-mount head 100 relative to the disk, a driver 330 that controls the drive source of the disk rotating device, a rotation position control device 340 that controls the rotation position of rotary-positioning device 320, and a main control device 350 that controls the entire testing apparatus.

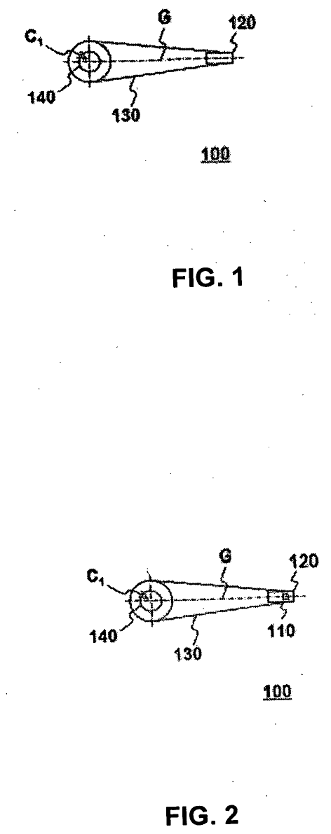

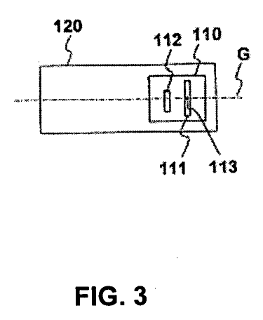

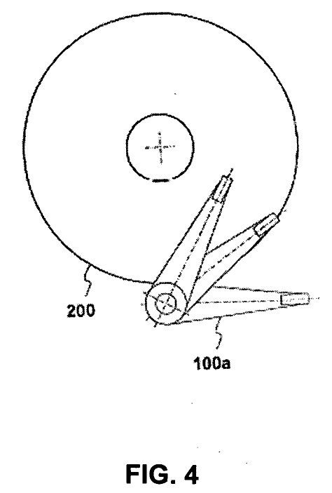

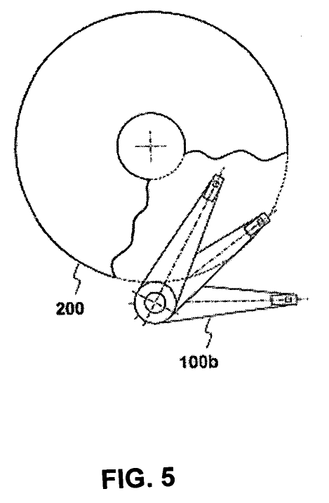

Una-mount head 100 has the same function and structure as shown in FIG. 1 and is the device under test. Una-mount head 100 is electrically connected to testing circuit M, which is not illustrated. Una-mount head 100 is tested by writing testing signals on each track on disk 200 and reading these signals that have been written. Both writing and reading can be performed by testing apparatus 300, or they can be performed, respectively, by a special testing apparatus for writing and a special testing apparatus for reading. In addition, una-mount head 100 can be tested by reading only using a pre-recorded disk.

Disk rotating device 310 comprises a rotating shaft 311, a motor 312, and a rotation speed detector 313. Rotating shaft 311 supports disk 200 so that it can be detached. Motor 312 is the drive source that rotates and drives rotating shaft 311. Rotational speed detector 313 detects the rotation speed of rotation shaft 311. Motor 312 and rotation speed detector 313 are connected to driver 330. Driver 330 controls motor 312 so that the rotational speed detected by rotation speed detector 313 is held constant. As a result, disk rotating device 310 can rotate disk 200 at a constant speed.

Rotary-positioning device 320 comprises an arm 321, a rotating shaft 322, and a motor 323. Arm 321 supports una-mount head 100 at one end so that it can be detached as needed. Moreover, arm 321 is supported at the other end by rotating shaft 322. Motor 323 is the drive source that rotates and drives rotating shaft 322. Rotation position detector 324 detects the rotation position of rotating shaft 322. Moreover, motor 323 and rotation-position detector 324 are connected to rotation-position control device 340. Rotation-position control device 340 controls motor 323 while referring to the rotation-position data detected by rotation-position detector 324. Rotation-positioning device 320 can thereby rotate and position una-mount head 100 so that una-mount head 100 and disk 200 are positioned by a pre-determined relative positional relationship. Furthermore, una-mount head 100 is positioned to the bottom face of disk 200. The method of positioning the head relative to the bottom surface of a suspended disk contributes to a reduction in the size of testing apparatus 300.

Disk rotating device 310 and rotary-positioning device 320 are supported on a base that is not illustrated.

Main control device 350 is a device that controls the entire testing apparatus 300. Driver 330, rotation-positioning control device 340, and testing circuit M (not shown) are connected to main control device 350. Main control device 350 controls the tests in accordance with the testing specifications requiring una-mount head 100.

The general flow of th testing method in accordance with the present invention is as follows. Main control device 350 controls driver 330 to rotate disk 200 at a pre-determined speed of rotation. Main control device 350 positions una-mount head 100 relative to disk 200 that is rotating at a pre-determined speed. Main control device 350 controls testing circuit M so that writing and reading are performed on una-mount head 100 and una-mount head 100 is tested.

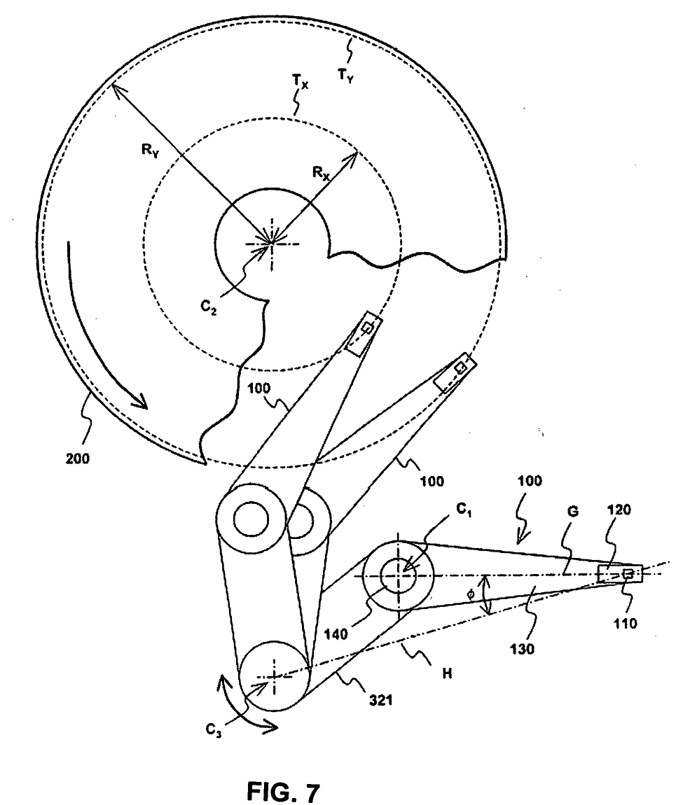

A top view of the testing apparatus 300 is shown in FIG. 7. In order to simplify the drawing and the corresponding description, FIG. 7 shows only disk 200, una-mount head 100, and arm 321. Moreover, for convenience, disk 200 is illustrated with a part thereof cut away.

Una-mount head 100 comprises slider 110, which has write element WR and read element RD (not shown), suspension 120 that supports slider 110, mounting plate 130 that supports suspension 120, and bearing 140. Straight line G is the gap center line of una-mount head 100. Gap center line G is a straight line passing through the center of the gap of write element WR of slider 110 that is orthogonal to the gap of the write element of slider 110.

Center C₂ is the center of disk 200 and is the center of rotating axis 311 shown in FIG. 6. Disk 200 rotates around center C₂. Center C₃ is the center of rotating shaft 322 shown in FIG. 6. Una-mount head 100 and arm 321 are positioned by being rotated around center C₃. Straight line H is the straight line that passes through the gap center (not illustrated) of una-mount head 100 and center C₃. The gap center (not illustrated) of una-mount head 100 is the center of write element WR of slider 110. In FIG. 7, una-mount head 100 is positioned on track Tx with a radius of Rx and on track Ty with a radius of Ry and at a position away from disk 200.

Rotary-positioning device 320 supports and positions una-mount head 100 such that the attitude of una-mount head 100 relative to center C₃ is tilted in comparison to the attitude of una-mount 100 relative to the center of rotation of una-mount head actually inside the disk drive while keeping una-mount head 100 away from center C₃. In other words, rotary-positioning device 320 supports and positions una-mount head 100 such that the angle formed by straight line H and gap center line G in FIG. 7 is offset in comparison to the angle that is formed by gap center line and the line that passes through swinging center of una-mount head and the gap center of una-mount head 100 in an actual disk drive.

An important testing specification in tests of una-mount head 100 is the relative positional relationship between una-mount head 100 and disk 200. Una-mount head 100 is usually tested after being positioned on two tracks of different radii, in tests in production lines. The skew angle of una-mount head 100 on each track is an important factor that effects testing results and it must be the same as the skew angle when una-mount head 100 and disk 200 are housed inside the disk drive device. Therefore, testing apparatus 300 is adapted so that the following formula is produced.

$$\begin{matrix}D = \sqrt{{L}^{2} - 2 L {R}_{X} cos ( {Θ}_{X} + φ ) + {R}_{X}^{2}} \\ = \sqrt{{L}^{2} - 2 L {R}_{X} cos ( {α}_{X} + φ + \frac{π}{2} ) + {R}_{X}^{2}}\end{matrix} \qquad ( Formula 1 )$$

D is the distance between center C₂ and center C₃ also referred to as the interaxial distance. R_{X} and R_{Y} are the radii of track positions T_{X} and T_{Y}, respectively, that are to be inspected. Θ is the angle that adds 90° to the necessary skew angle α_{X} of una-mount head 100 on R_{X}. Θ_{Y} is the angle that adds 90° to the necessary skew angle α_{Y} of una-mount head 100 at R_{Y}. R_{X} and R_{Y}, and α_{X} and α_{Y} are prescribed by the testing specifications. Moreover, φ is the angle between the gap center line G and the straight line that passes through center C₃ and the gap center of una-mount head 100. φ is called the offset angle. L is the distance between the gap center (not shown) of una-mount head 100 and center C₃ of rotating shaft 322 and is represented by the following formula. L is also called the swinging radius.

$$\begin{matrix}L = \frac{ {R}_{Y}^{2} - {R}_{X}^{2}}{2 \{ {R}_{Y} cos ( {Θ}_{Y} + φ ) - {R}_{X} cos ( {Θ}_{X} + φ ) \}} \\ = \frac{{R}_{Y}^{2} - {R}_{X}^{2}}{2 \{ {R}_{Y} cos ( {α}_{Y} + φ + \frac{π}{2} ) - {R}_{X} cos ( {α}_{X} + φ + \frac{π}{2} ) \}}\end{matrix} \qquad ( Formula 2 )$$

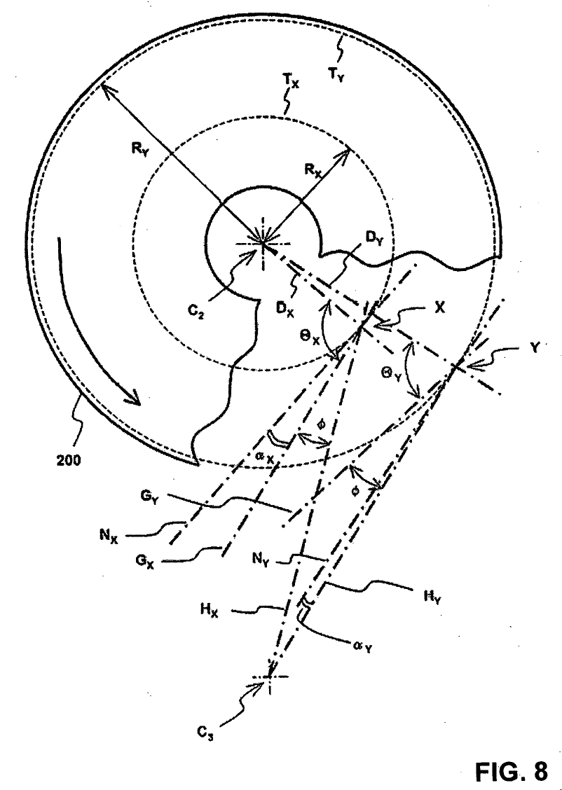

Please refer to FIG. 8 for a better understanding of formulas 1 and 2. FIG. 8 is the drawing in FIG. 7 in which several elements have been eliminated and several elements have been added. Center C₂ is the center of disk 200. It is also the center of rotating shaft 311 in FIG. 6. Center C₃ is the center of rotating shaft 322 shown in FIG. 6. Position X is the position of the gap center of una-mount head 100 positioned on track T_{X} with radius R_{X}. Position Y is the position of the gap center of una-mount head 100 positioned on track T_{Y} with radius R_{Y}. Straight line D_{X} is the straight line that passes through position X and center C₂, which is the center of disk 200. Straight line D_{Y} is the straight line that passes through center C₂ and position Y. Straight line G_{X} is the gap center line of una-mount head 100 positioned on track T_{X}. Straight line G_{Y} is the gap center line of una-mount head 100 positioned on track T_{Y}. Straight line H_{X} is the straight line that passes through position X and center C₃. Straight line H_{Y} is the straight line that passes through position Y and center C₃. Θ_{X} is the angle formed by straight line D_{X} and gap center line G_{X}. Θ_{Y} is the angle formed by straight line D_{Y} and gap center line G_{Y}. Skew angle α_{X} cited in formulas 1 and 2 is the angle that is formed by gap center line G_{X} and tangent N_{X} of track T_{X} at position X. Skew angle α_{Y} cited in formula 2 is the angle that is formed by gap center line G_{Y} and tangent N_{Y} of track T_{Y} at position Y. Formulas 1 and 2 are easily derived if the cosine theorem is used while referring to FIG. 8.

Offset angle φ, interaxial distance D, and oscillation radius L can be determined by giving an appropriate value to one of these three parameters and deriving the other two parameters. The length of arm 321, that is, the distance between center C₁ and center C₃, can be found from the distance between center C₁ and the gap center of una-mount head 100, derived offset angle φ, and derived swinging radius L using the cosine theorem

Moreover, offset angle φ,interaxial distance D, and oscillation radius L should be determined during testing of una-mount head 100 such that only formula 1 is satisfied when it is necessary to position the head on only one track.

Alternatively, the present invention can be modified as long as the head is supported such that the attitude of the head relative to the swinging center of the rotary-positioning means is tilted in comparison to the attitude of the head relative to the swinging center of the head in an actual disk drive. Another embodiment is described hereafter as a modified example.

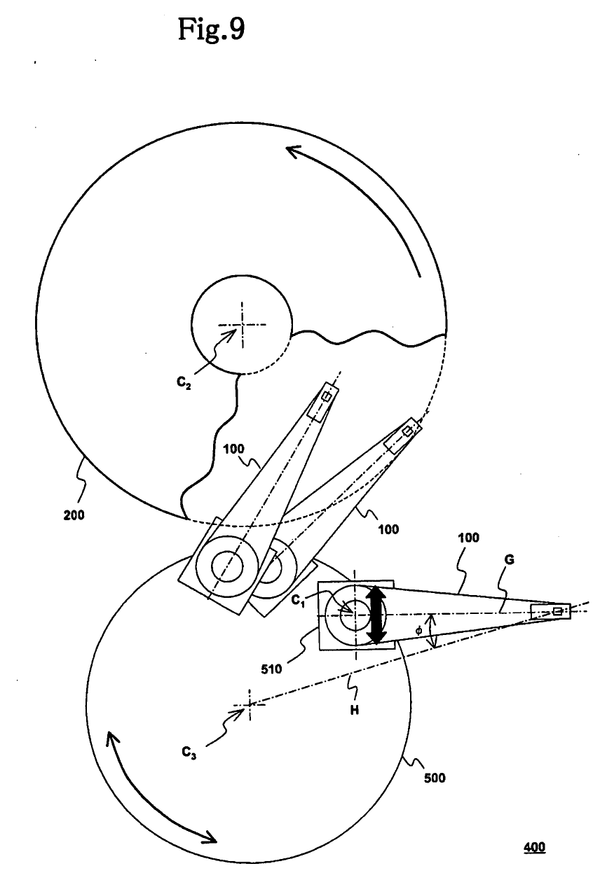

A second embodiment is an apparatus for testing a head or disk and a schematic drawing thereof as shown in FIG. 9. FIG. 9 is a top view showing part of the testing apparatus.

Testing apparatus 400 in FIG. 9 is testing apparatus 300 shown in FIG. 6 with rotary-positioning device 320 replaced by rotary stage 500. The other structural elements of testing apparatus 300 similarly comprise testing apparatus 400.

Rotary stage 500 is a disk-shaped positioning device and turns about center C₃. Rotary stage 500 comprises fine positioning device 510 near the periphery thereof. Fine positioning device 510 is a positioning means for fine positioning in a linear direction. The positioning accuracy of fine positioning device 510 is generally higher than the positioning accuracy of rotary stage 500. Una-mount head 100 is supported so that it can be attached and detached and positioned by fine positioning device 510. By means of the present embodiment, una-mount head 100 is positioned orthogonal to gap center line G by fine positioning device 510. This positioning direction is roughly consistent with the direction of the width of the track. Moreover, una-mount head 100 is supported so that center C₁ and bearing center C₃ of una-mount head 100 are kept apart. Una-mount head 100 is supported so that the gap center line G of una-mount head 100 is tilted in comparison to the line that passes through center C₃ and the gap center (notshown) of una-mount head 100.

Rotary stage 500 is much stiffer when compared to arm 321 described in the first embodiment and capable of supporting una-mount head 100 with higher stability. Consequently, rotary stage 500 can increase the mechanical resonance frequency at the tip of una-mount head 100. As a result, it becomes easier to control positioning and so forth with testing apparatus 400 and measurement errors during tests can be suppressed.

Each of the embodiments described above is an apparatus for testing the head based on a disk, but it becomes a disk testing apparatus when the disk is tested with the head as a reference. Thus, the present invention is ideally and equally applicable in either case.

Moreover, in each embodiment the gap center is the center of the gap of the write element of the slider, but it can also be the center of the gap of the read element of the slider. In addition, the gap center line is the straight line passing through the center of this gap orthogonal to the gap of the read element of the slider.

While we have shown and described several embodiments in accordance with our invention, it should be clearly understood that numerous similar modifications are possible for one skilled in the art. Therefore, we do not wish to be limited to the details shown and described but instead all changes and modifications within the scope of the appended claims are also within the scope of the present invention.

What we claim is:

1. A testing apparatus for testing a disk and/or a head of a disk drive, said apparatus comprises:
a disk rotation device that rotates said disk; and
a rotary-positioning device that rotates and positions said head, with said rotary-positioning device supporting said head such that an attitude of said head relative to a center of rotation of said rotary-positioning device is tilted in comparison to said attitude of said head relative to said center of rotation of said head in said disk drive.

2. The testing apparatus according to claim 1, wherein said rotary-positioning device supports said head such that an angle formed by a gap center line of said head and a line that passes through said center of rotation of said rotary-positioning device and said gap center of said head is offset to an angle formed by said gap center line of said head and a line that passes through the center of rotation of said head and the gap center of said head in said disk drive.

3. The testing apparatus according to claim 2, wherein said testing apparatus is adapted so that the following formula is satisfied when said head is positioned on a first track on said disk and a distance between said center of rotation of said disk rotation device and said center of rotation of said rotary-positioning device is D, a distance between said center of rotation of said rotary-positioning device and said gap center of said head is L, a radius of said first track is R_{X}, a necessary skew angle of said head on said first track is α_{X}, and said offset angle is φ:
$$D = \sqrt{{L}^{2} - 2 L {R}_{X} cos ( {α}_{X} + φ + \frac{π}{2} ) + {R}_{X}^{2}}$$

4. The testing apparatus according to claim 3, said testing apparatus being adapted so that the following formulas are satisfied when said head is positioned on said first track and a second track on said disk and said distance between the center of rotation of said disk rotation device and the center of rotation of said rotary-positioning device is D, said distance between said center of rotation of said rotary-positioning device and the gap center of said head is L, said radius of said first track is R_{X}, the radius of said second track is R_{Y}, said necessary skew angle of said head on said first track is α_{X}, said necessary skew angle of said head on said second track is α_{Y}, and said offset angle is φ:
$$D = \sqrt{{L}^{2} - 2 L {R}_{X} cos ( {α}_{X} + φ + \frac{π}{2} ) + {R}_{X}^{2}}$$
$$L = \frac{{R}_{Y}^{2} - {R}_{X}^{2}}{2 \{ {R}_{Y} cos ( {α}_{Y} + φ + \frac{π}{2} ) - {R}_{X} cos ( {α}_{X} + φ + \frac{π}{2} ) \}}$$

5. The testing apparatus according t claim 1, wherein said head is a una-mount head.

6. A method for testing a disk and/or head of a disk drive using a disk rotation device and a rotary-positioning device, said method comprising:
supporting and positioning said head by said rotary-positioning device such that an attitude of said head relative to a center of rotation of said rotation-positioning device is tilted in comparison with said attitude of said head relative to said center of rotation of said head in said disk drive.

7. The method according to claim 6, wherein said head is supported by said rotary-positioning device such that an angle formed by a gap center line of said head and a line that passes through said center of rotation of said rotary-positioning device and said gap center of said head is offset in comparison to an angle formed by said gap center line of said head and said line that passes through said center of rotation of said head and said gap center of said head in said disk drive.

8. The method according to claim 7, wherein the following formula is satisfied when said head is positioned on a first track on said disk; and a distance between the center of rotation of said disk rotation device and said center of rotation of said rotary-positioning device is D, a distance between said center of rotation of said rotary-positioning device and said gap center of said head is L, a radius of said first track is R_{X}, a necessary skew angle of said head on said first track is α_{X}, and an offset angle is φ:
$$D = \sqrt{{L}^{2} - 2 L {R}_{X} cos ( {α}_{X} + φ + \frac{π}{2} ) + {R}_{X}^{2}}$$

9. The method according to claim 8, wherein the following formulas are produced when said head is positioned on said first track and a second track on said disk; and said distance between the center of rotation of said disk rotation device and said center of rotation of said rotary-positioning device is D, said distance between said center of rotation of said rotation-positioning device and said gap center of said head is L, said radius of said first track is R_{X}, a radius of said second track is R_{Y}, a necessary skew angle of said head on said first track is α_{X}, a necessary skew angle of said head on said second track is α_{Y}, and said offset angle is φ.
$$D = \sqrt{{L}^{2} - 2 L {R}_{X} cos ( {α}_{X} + φ + \frac{π}{2} ) + {R}_{X}^{2}}$$
$$L = \frac{{R}_{Y}^{2} - {R}_{X}^{2}}{2 \{ {R}_{Y} cos ( {α}_{Y} + φ + \frac{π}{2} ) - {R}_{X} cos ( {α}_{X} + φ + \frac{π}{2} ) \}}$$

10. The method according to claim 6, wherein said head is a una-mount head.
